(19) United States
(12) Patent Application Publication
(10) Pub. No.: US 2025/0333579 A1
(43) Pub. Date: Oct. 30, 2025

(54) COMPOSITION AND PACKAGE STRUCTURE

(71) Applicant: INDUSTRIAL TECHNOLOGY RESEARCH INSTITUTE, Hsinchu (TW)

(72) Inventors: Yu-Ju KUO, Zhubei City (TW); Dong-Sen CHEN, Zhudong Township (TW); Pei-Ying LIU, Zhudong Township (TW); Jheng-Ying LI, Taoyuan City (TW)

(73) Assignee: INDUSTRIAL TECHNOLOGY RESEARCH INSTITUTE, Hsinchu (TW)

(21) Appl. No.: 19/019,835

(22) Filed: Jan. 14, 2025

(30) Foreign Application Priority Data
Apr. 26, 2024 (TW) 113115760

(51) Int. Cl. C08K 5/00; C08K 5/14; H01L 21/683; H10H 20/01; H10K 71/80

(52) U.S. Cl. CPC C08K 5/0025; C08K 5/14; H01L 21/6836; H01L 2221/68386; H10H 20/036; H10K 71/80

(57) ABSTRACT

A composition and a package structure including a polyimide film prepared from the composition are provided. The composition includes 100 parts by weight of a polyimide and 1-10 parts by weight of a crosslinking agent. The polyimide is composed of n number of a main-chain repeating unit and two end-capping groups, where n/2 is from 10 to 550.

### CROSS REFERENCE TO RELATED APPLICATIONS

This application claims priority of Taiwan Patent Application No. 113115760, filed on Apr. 26, 2024, the entirety of which is incorporated by reference herein.

### TECHNICAL FIELD

The disclosure relates to a composition and package structure.

### BACKGROUND

As semiconductor devices become thinner, temporary bonding/debonding technology has emerged as one of the key developments in recent years. Because thinner devices are fragile and lack support, they require the use of a temporary adhesive to bond the workpiece (such as a wafer) to a substrate. This allows subsequent processings, such as wiring or interconnection, to be performed on the workpiece. Once processing is complete, the temporary adhesive can be removed, separating the workpiece from the substrate.

Since semiconductor manufacturing processes often involve high-temperature operations like tin soldering and reflow soldering, which typically operate at temperatures greater than 250° C., the temporary adhesive not only needs to provide good adhesion but it must also have thermal tolerance and be easy to be removed. During processing, the temporary adhesive holds the workpiece securely in place on the substrate, withstanding the high-temperature conditions of semiconductor manufacturing. After processing, the adhesive can easily be peeled off and cleaned.

In the automated process of removing the workpiece from the substrate, mechanical lift-off (MLO) or laser lift-off (LLO) processes are commonly used. For small workpieces (such as micro light-emitting diode devices), the mechanical lift-off process can easily damage the workpiece (such as causing contact detachment), whereas the laser lift-off process is less likely to harm the workpiece. However, not all temporary adhesives are suitable for use with the laser lift-off process.

Therefore, there is a need for a novel adhesive material suitable for the laser lift-off process.

### SUMMARY

According to embodiments of the disclosure, the disclosure provides a composition. The composition includes 100 parts by weight of a polyimide and 1-10 parts by weight of a crosslinking agent. The polyimide consists of n number of a main-chain repeating unit and two end-capping groups, wherein n/2 is 10 to 550.

According to embodiments of the disclosure, the disclosure also provides a package structure. The package structure includes a substrate; a polyimide film disposed on the substrate, wherein the polyimide film may be a cured product of the composition of the disclosure; and, an electronic element disposed on the polyimide film.

A detailed description is given in the following embodiments.

### BRIEF DESCRIPTION OF THE DRAWINGS

The present disclosure can be more fully understood by reading the subsequent detailed description and examples with references made to the accompanying drawings, wherein:

FIG. 1 is a schematic view of the package structure according to embodiments of the disclosure.

FIG. 2 is a flow chart illustrating the method for dismantling a package structure according to an embodiment of the disclosure.

### DETAILED DESCRIPTION

The composition and package structure of the disclosure are described in detail in the following description. In the following detailed description, for purposes of explanation, numerous specific details and embodiments are set forth in order to provide a thorough understanding of the present disclosure. The specific elements and configurations described in the following detailed description are set forth in order to clearly describe the present disclosure. It will be apparent, however, that the exemplary embodiments set forth herein are used merely for the purpose of illustration, and the inventive concept may be embodied in various forms without being limited to those exemplary embodiments. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments. As used herein, the term “about” in quantitative terms refers to plus or minus an amount that is general and reasonable to persons skilled in the art.

Furthermore, the use of ordinal terms such as “first”, “second”, “third”, etc., in the disclosure to modify an element does not by itself connote any priority, precedence, order of one claim element over another or the temporal order in which it is formed, but are used merely as labels to distinguish one claim element having a certain name from another element having the same name (but for use of the ordinal term) to distinguish the claim elements.

It should be noted that the elements or devices in the drawings of the disclosure may be present in any form or configuration known to those skilled in the art. In addition, the expression “a layer overlying another layer”, “a layer is disposed above another layer”, “a layer is disposed on another layer”, and “a layer is disposed over another layer” may refer to a layer that directly contacts the other layer, and they may also refer to a layer that does not directly contact the other layer, there being one or more intermediate layers disposed between the layer and the other layer.

The disclosure provides a composition, and a package structure. According to embodiments of the disclosure, the composition of the disclosure includes a polyimide and a crosslinking agent. The number of main-chain repeating units in the polyimide could be kept within a specific range (i.e., controlling the main-chain length of the polyimide) through the use of a capping agent, and the adhesion properties and thermal tolerance of the polyimide film made from the polyimide-containing composition are improved. Further, when removing the electronic element from the substrate in the subsequent laser lift-off process, the stress could be reduced due to the introduction of the specific polyimide film. Through the selection of a specific capping agent, the polyimide can undergo a crosslinking reaction with a crosslinking agent. In addition, since the selected capping agent and crosslinking agent can absorb light at specific wavelengths, the polyimide film can absorb energy to undergo a photodegradation reaction during the laser lift-off process, thereby enabling the removal of the electronic element from the substrate and preventing the interconnect layer arranged on the electronic element from damages. As a result, the electronic element can be smoothly separated from the substrate during the transfer process.

According to embodiments of the disclosure, the disclosure provides a composition, wherein the composition includes 100 parts by weight of polyimide and 1-10 parts by weight (such as 2 parts by weight, 3 parts by weight, 4 parts by weight, 5 parts by weight, 6 parts by weight, 7 parts by weight, 8 parts by weight, or 9 parts by weight) of crosslinking agent.

According to embodiments of the disclosure, the polyimide consists of n number of a main-chain repeating unit and two end-capping groups, wherein n/2 (the ratio of the number of main-chain repeating units to the number of end-capping groups) is within a range of 10 to 550, such as about 15, 20, 30, 50, 80, 100, 120, 150, 200, 250, 300, 350, 400, 450, 500, or 520. When the n/2 value is too high, the polyimide film made from the composition is less prone to photodegradation and is unsuitable for the laser lift-off process. When the n/2 value is too low, the polyimide film made from the composition will have lower adhesion and thermal tolerance.

According to embodiments of the disclosure, the composition includes polyimides with various numbers of main-chain repeating units, and the number of main-chain repeating units of each polyimide meets the following condition: n/2 is within a range of 10 to 550.

According to embodiments of the disclosure, the main-chain repeating unit may be derived from a reaction of a diamine and a dianhydride.

According to embodiments of the disclosure, the end-capping group may be derived from a reaction of the diamine and an anhydride compound (capping agent), or the end-capping group may be derived from a reaction of the dianhydride and an amine compound (capping agent).

According to embodiments of the disclosure, the anhydride compound (capping agent) may be

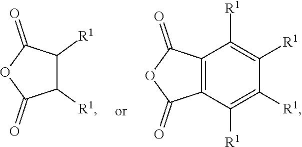

wherein R¹ is independently hydrogen, fluorine, hydroxyl group, amino group, C1-C8 alkyl group, C1-C8 fluoroalkyl group, C6-C12 aryl group, C2-C8 carboxyalkyl group, C2-C8 alkenyl group, C2-C8 isocyanatoalkyl group, C1-C8 alkylamino group, C4-C8 acryloxyalkyl group, C5-C9 methacryloxyalkyl group, C3-C8 epoxyalkyl group, C4-C8 oxetanylalkyl group, or 3,4-epoxycyclohexyl group. According to embodiments of the disclosure, in the anhydride capping agent, at least one R¹ is independently hydroxyl group, C2-C8 carboxyalkyl group, C2-C8 alkenyl group, C2-C8 isocyanatoalkyl group, C4-C8 acryloxyalkyl group, C5-C9 methacryloxyalkyl group, C3-C8 epoxyalkyl group, C4-C8 oxetanylalkyl group, or 3,4-epoxycyclohexyl group. According to embodiments of the disclosure, the anhydride capping agent may be allylsuccinic anhydride.

According to embodiments of the disclosure, the amine compound (capping agent) may be

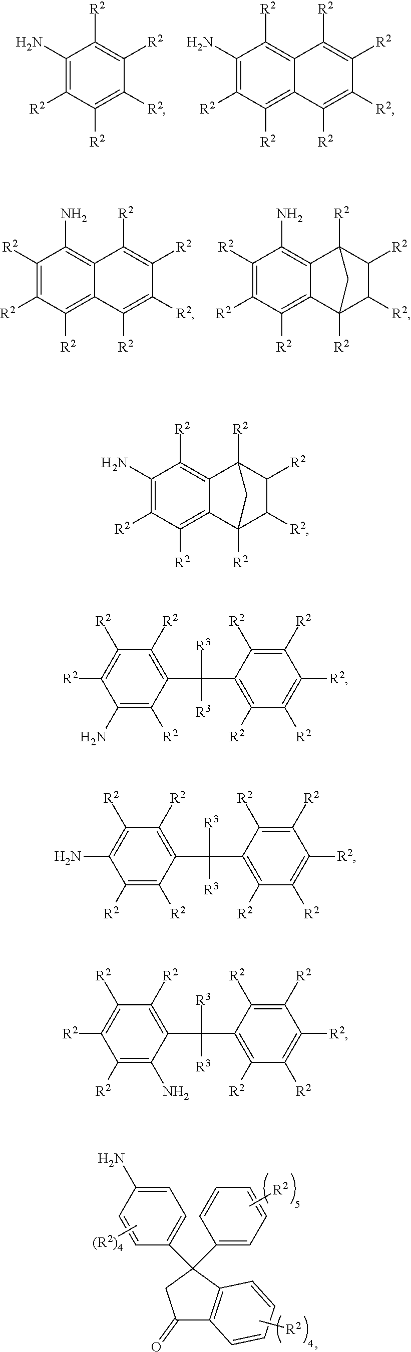

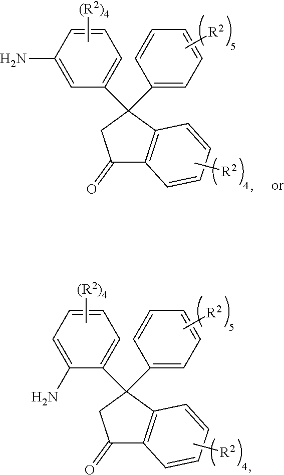

wherein R² is independently hydrogen, fluorine, hydroxyl group, C1-C8 alkyl group, C1-C8 fluoroalkyl group, C6-C12 aryl group, C2-C8 carboxyalkyl group, C2-C8 alkenyl group, C2-C8 isocyanatoalkyl group, C4-C8 acryloxyalkyl group, C5-C9 μmethacryloxyalkyl group, C3-C8 epoxyalkyl group, C4-C8 oxetanylalkyl group, or 3,4-epoxycyclohexyl group; and, R³ is independently hydrogen, fluorine, C1-C4 alkyl group, or C1-C4 fluoroalkyl group. According to embodiments of the disclosure, in the amine capping agent, at least one R² is independently hydroxyl group, C2-C8 carboxyalkyl group, C2-C8 alkenyl group, C2-C8 isocyanatoalkyl group, C4-C8 acryloxyalkyl group, C5-C9 μmethacryloxyalkyl group, C3-C8 epoxyalkyl group, C4-C8 oxetanylalkyl group, or 3,4-epoxycyclohexyl group.

According to embodiments of the disclosure, C1-C8 alkyl group of the disclosure may be a linear or branched alkyl group. According to embodiments of the disclosure, C1-C8 alkyl group may be methyl, ethyl, propyl, butyl, pentyl, hexyl, heptyl, octyl, or an isomer thereof. For example, C1-C8 alkyl group may be methyl, ethyl, n-propyl, isopropyl, n-butyl, sec-butyl, iso-butyl, or tert-butyl.

According to embodiments of the disclosure, C1-C8 fluoroalkyl group of the disclosure can be alkyl group in which a part of or all hydrogen atoms bonded on the carbon atom are replaced with fluorine atoms, and C1-C8 fluoroalkyl group can be linear or branched, such as fluoromethyl, fluoroethyl, fluoropropyl, fluorobutyl, fluoropentyl, fluorohexyl, or an isomer thereof. Herein, fluoromethyl group may be monofluoromethyl group, difluoromethyl group or trifluoromethyl group, and fluoroethyl may be monofluoroethyl group, difluoroethyl group, trifluoroethyl group, tetrafluoroethyl, or perfluoroethyl

According to embodiments of the disclosure, C6-C12 aryl group of the disclosure may be phenyl group, biphenyl group, or naphthyl group.

According to embodiments of the disclosure, C2-C8 alkenyl group of the disclosure may be a linear or branched alkenyl group and includes at least one carbon-carbon double bond, such as ethenyl, propenyl, butenyl, pentenyl, hexenyl, heptenyl, octenyl, or an isomer thereof.

According to embodiments of the disclosure, C2-C8 carboxyalkyl group of the disclosure can be C1-C7 alkyl group in which a hydrogen atom bonded on the carbon atom is replaced with a carboxy group.

According to embodiments of the disclosure, C2-C8 isocyanatoalkyl group of the disclosure can be C1-C7 alkyl group in which a hydrogen atom bonded on the carbon atom is replaced with an isocyanato group.

According to embodiments of the disclosure, C4-C8 acryloxyalkyl group of the disclosure can be C1-C5 alkyl group in which a hydrogen atom bonded on the carbon atom is replaced with an acryloxyalkyl group.

According to embodiments of the disclosure, C5-C9 μmethacryloxyalkyl group of the disclosure can be C1-C5 alkyl group in which a hydrogen atom bonded on the carbon atom is replaced with a methacryloxyalkyl group.

According to embodiments of the disclosure, C3-C8 epoxyalkyl group of the disclosure can be C1-C6 alkyl group in which a hydrogen atom bonded on the carbon atom is replaced with an oxiranyl group.

According to embodiments of the disclosure, C4-C8 oxetanylalkyl group of the disclosure can be C1-C5 alkyl group in which a hydrogen atom bonded on the carbon atom is replaced with an oxetanyl group.

According to embodiments of the disclosure, the main-chain repeating unit may be derived from a reaction of a diamine and a dianhydride.

According to embodiments of the disclosure, the diamine may be 1,3-bis(4-aminophenoxy)benzene (TPE-R), 3,3′-oxydianiline (3,3′-ODA), 4,4′-oxydianiline (4,4′-ODA), bis(4-aminophenyl) terephthalate (BPTP), 1,3-bis(3-aminophenoxy)benzene (APB-N), 4,4′-oxybis[3-(trifluoromethyl)aniline](TMDA), 2,2-bis[4-(4-aminophenoxy)phenyl]propane (BAPP), 4,4′-bis(4-aminophenoxy)benzophenone (BAPK), 4,4′-[Naphthalene-2,7-diylbis(oxy)]dianiline (NDA), 4,4′-(1,1′-biphenyl-4,4′-diyldioxy)dianiline (BAPB), 2,2-bis[4-(4-aminophenoxy)phenyl]hexafluoropropane (HFBAPP), isophorone diamine (IPDA), 4-methylcyclohexane-1,3-diamine (HTDA), 4,4′-methylenebis(cyclohexylamine) (PACM), 4,4′-Methylenebis(2-methylcyclohexylamine) (MACM), bis(aminomethyl)norbornane (NORB), adamantane-1,3-diamine (ADDA), octahydro-4,7-methanoindene-1(2),5(6)-dimethanamine, 2,2′-bis(trifluoromethyl)benzidine (TFMB), 2,2′-dimethyl-4,4′-biphenyldiamine (m-TBHG), O-tolidine, 4,4′-methylenedianiline (4,4′-DAPM), 3,4′-methylenedianiline (3,4′-DAPM), 4,4′-diamino-3,3′-dimethyldiphenylmethane (MDA), 4,4′-methylenebis(2-ethylbenzenamine) (MOEA), 4,4′-methylenebis(2,6-diethylaniline) (MDEA), 9,10-bis(4-aminophenyl)anthracene, p-phenylenediamine, m-phenylenediamine, o-phenylenediamine, 2,6-naphthalenediamine, 2,6-anthracenediamine, 4,4′-diamino-p-terphenyl, 2,2-bis(4-aminophenyl) hexafluoropropane (AAF), α,α′-bis(4-aminophenyl)-1,4-diisopropylbenzene (Bisaniline P), 9,9-bis(4-aminophenyl)fluorene (FDA), 3,3′,5,5′-tetramethylbenzidine (TMB), 4,4′-diamino-2,2′-dimethoxybiphenyl (m-DS), 4,4′-diaminobenzophenone (DABP), bis[4-(4-aminophenoxy)phenyl]sulfone (BAPS), 4,4′-diaminobenzanilide (DABA), or a combination thereof.

According to embodiments of the disclosure, the dianhydride may be 3,4′-oxydiphthalic anhydride (3,4′-ODPA), 2,2-bis[4-(3,4-dicarboxyphenoxy)phenyl]propanedianhydride (BPADA), p-phenylenebis(trimellitate anhydride) (TAHQ), 2,6-dihydroxynaphthalene bis(trimellitate anhydride) (2,6-TANA), pyromellitic dianhydride (PMDA), cyclobutane-1,2,3,4-tetracarboxylic dianhydride (CBDA), 1,2,4,5-cyclohexanetetracarboxylic dianhydride (H-PMDA), bicyclo[2.2.2]oct-7-ene-2,3,5,6-tetracarboxylic dianhydride (B1317), bicyclooctanetetracarboxylic dianhydride (BODA), dicyclohexyl-3,4,3′,4′-tetracarboxylic dianhydride (H-BPDA), [3-(carboxymethyl)-1,2,4-cyclopentanetricarboxylic acid 1,4:2,3-dianhydride](TCA-AH), 1,2,3,4-butanetetracarboxylic dianhydride (BDA), 3,3′, 4,4′-biphenyl tetracarboxylic dianhydride (4,4′-BPDA), 2,3,3′,4′-biphenyltetracarboxylic dianhydride (3,4′-BPDA), 5-[4-(1,3-dioxo-2-benzofuran-5-yl)phenyl]-2-benzofuran-1,3-dione (1,4-PIB), 5-[3-(1,3-dioxo-2-benzofuran-5-yl)phenyl]-2-benzofuran-1,3-dione (1,3-PIB), 4,4′-(hexafluoroisopropylidene)diphthalic anhydride (6FDA), 3,3′, 4,4′-benzophenonetetracarboxylic dianhydride (BTDA), 9,9-bis(3,4-dicarboxyphenyl)fluorene dianhydride (BPAF), N,N′-(2,2′-bis(trifluoromethyl)-[1,1′-biphenyl]-4,4′-diyl)bis(1,3-dioxo-1,3-dihydroisobenzofuran-5-carboxamide) (TA-TFMB), 1,2,3,4-cyclopentanetetracarboxylic dianhydride (CPDA), or a combination thereof.

According to embodiments of the disclosure, the crosslinking agent of the disclosure may be a compound having at least two reactive groups, wherein the reactive groups can react with the end-capping groups of the polyimide, wherein the reactive group may be isocyanato group, hydroxy group, epoxy group, acryloxy group, or methacryloxy group.

According to embodiments of the disclosure, the crosslinking agent of the disclosure may be trimethylol propane triglycidyl ether, glycerol triglycidyl ether, glycerol propoxylate triglycidyl ether, N,N-diglycidyl-4-glycidyloxyaniline, tris(2,3-epoxypropyl)isocyanurate, o-cresol novolak epoxy resin, triphenylol methane triglycidyl ether, 4,4′-methylenebis(N,N-diglycidylaniline), tetraphenylolethane glycidyl ether, poly(ethylene adipate) diol, poly(1,4-butylene adipate) diol, poly(ethylene dodecanoate) diol, poly(1,6-hexathylene adipate) diol, polyethylene glycol (PEG), polypropylene glycol (PPG), polytetramethylene ether glycol (PTMEG), ethylene glycol, 1,3-propylene glycol, glycerol, 1,4-butylene glycol, 1,5-pentylene glycol, neopentylene glycol, 1,6-hexylene glycol, 1,7-heptylene glycol, 2,5-furandiol, toluene diisocyanate (TDI), phenylene diisocyanate, 4,4′-diphenyl diisocyanate, naphthalene diisocyanate (NDI), diphenylmethane diisocyanate (MDI), toluidine diisocyanate (TODI), hexamethylene diisocyanate (HDI), trimethylhexamethylene diisocyanate, 2,6-diisocyanate methyl caprate, 1,3-cyclopentane diisocyanate, norbornane diisocyanate (NBDI), bis(isocyanatomethyl)cyclohexane (H6XDI), 1,6-hexanediol diacrylate (HDDA), 1,6-hexanediol dimethacrylate, 1,9-bis(acryloyloxy)nonane, 1,9-bis(methacryloyloxy)nonane, 1,10-decanediol diacrylate (DDDA), 1,10-decanediol dimethacrylate, neopentyl glycol diacrylate, neopentyl glycol dimethacrylate, polyethylene glycol (PEG) (200) diacrylate (PEG200DA), polyethylene glycol (PEG) (400) diacrylate (PEG400DA), pentaerythritol tetraacrylate (PETTA), dipentaerythritol hexaacrylate (DPHA), di(trimethylolpropane) tetraacrylate (Di-TMPTTA), trimethylolpropane triacrylate (TMPTMA), di(polypentaerythritol) polyacrylate, polypentaerythritol polyacrylate, polybutadiene diacrylate (PBDDA), 3-methyl 1,5-pentanediol diacrylate (MPDA), ethoxylated 3 bisphenol A diacrylate (BPA3EODA), propoxylated 3 trimethylolpropane triacrylate (TMP3POTA), ethoxylated pentaerythritol tetraacrylate, ethoxylated 6 trimethylolpropane triacrylate (TMP6EOTA), ethoxylated 9 trimethylolpropane triacrylate (TMP9EOTA), ethoxylated 4 bisphenol A diacrylate (BPA4EODA), esterdiol diacrylate (EDDA), alkoxylated diacrylate, propoxylated 2 neopentyl glycol diacrylate (PONPGDA), propoxylated 3 glyceryl triacrylate (GPTA), urethane acrylate resin, or a combination thereof.

According to embodiments of the disclosure, the composition of the disclosure may further include a 0.1-2 parts by weight (such as 0.2 parts by weight, 0.5 parts by weight, 1 part by weight, or 1.5 parts by weight) initiator, wherein the initiator can generate free radicals, promoting the reaction between the reactive functional groups (end-capping groups) at the polyimide chain ends and the crosslinking agent. The initiator may be azo compound, cyanovaleric-acid-based compound, peroxide, benzoin-based compound, acetophenone-based compound, thioxanthone-based compound, ketal compound, benzophenone-based compound, α-aminoacetophenone compound, acylphosphine oxide compound, biimidazole-based compound, triazine-based compound, or a combination thereof.

According to embodiments of the disclosure, the azo compound may include 2,2′-azobis(2,4-dimethyl valeronitrile), dimethyl 2,2′-azobis(2-methylpropionate), 2,2′-azobisisobutyronitrile (hereafter referred to as AIBN), 2,2′-azobis(2-methylisobutyronitrile), 1,1′-azobis(cyclohexane-1-carbonitrile), 2,2′-azobis[N-(2-propenyl)-2-methylpropionamide], 1-[(cyano-1-methylethyl)azo]formamide, 2,2′-azobis(N-butyl-2-methylpropionamide), or 2,2′-azobis(N-cyclohexyl-2-methylpropionamide). The peroxide may include benzoyl peroxide (BPO), 1,1-bis(tert-butylperoxy)cyclohexane, 2,5-bis(tert-butylperoxy)-2,5-dimethylcyclohexane, 2,5-bis(tert-butylperoxy)-2,5-dimethyl-3-cyclohexyne, bis(1-(tert-butylperoxy)-1-methylethyl)benzene, tert-butyl hydroperoxide, tert-butyl peroxide, tert-butyl peroxybenzoate, cumene hydroperoxide, cyclohexanone peroxide, dicumyl peroxide, or lauroyl peroxide. The benzoin-based compound may include benzoin, benzoin methyl ether, or benzoin dimethyl ether. The acetophenone-based compound may include p-dimethylamino-acetophenone, α,α′-dimethoxyazoxy-acetophenone, 2,2′-dimethyl-2-phenyl-acetophenone, p-methoxy-acetophenone, 2-methyl-1-(4-methylthiophenyl)-2-morpholino-1-propanone, or 2-benzyl-2-N,N-dimethylamino-1-(4-morpholinophenyl)-1-butanone. The benzophenone-based compound may include benzophenone, 4,4-bis(dimethylamino)benzophenone, 4,4-bis(diethylamino)benzophenone, 2,4,6-trimethylaminobenzophenone, methyl-o-benzoyl benzoate, 3,3-dimethyl-4-methoxybenzophenone, or 3,3,4,4-tetra(t-butylperoxycarbonyl)benzophenone. The thioxanthone-based compound may include thioxanthone, 2,4-diethyl-thioxanthone, or thioxanthone-4-sulfone. The biimidazole-based compound may include 2,2′-bis(o-chlorophenyl)-4,4′,5,5′-tetraphenyl-biimidazole, 2,2′-bis(o-fluorophenyl)-4,4′,5,5′-tetraphenyl-biimidazole, 2,2′-bis(o-methylphenyl)-4,4′,5,5′-tetraphenyl-biimidazole, 2,2′-bis(o-methoxyphenyl)-4,4′,5,5′-tetraphenyl-biimidazole, 2,2′-bis(o-ethylphenyl)-4,4′,5,5′-tetraphenyl-biimidazole, 2,2′-bis(p-methoxyphenyl)-4,4′,5,5′-tetraphenyl-biimidazole, 2,2′-bis(2,2′,4,4′-tetramethoxyphenyl)-4,4′,5,5′-tetraphenyl-biimidazole, 2,2′-bis(2-chlorophenyl)-4,4′,5,5′-tetraphenyl-biimidazole, or 2,2′-bis(2,4-dichlorophenyl)-4,4′,5,5′-tetraphenyl-biimidazole. The acylphosphine oxide compound may include 2,4,6-trimethylbenzoyl diphenylphosphine oxide or bis(2,6-dimethoxybenzoyl)-2,4,4-trimethylpentylphosphine oxide. Triazine-based compound may include 3-{4-[2,4-bis(trichloromethyl)-s-triazine-6-yl]phenylthio}propionic acid, 1,1,1,3,3,3-hexafluoroisopropyl-3-{4-[2,4-bis(trichloromethyl)-s-triazine-6-yl]phenylthio}propionate, ethyl-2-{4-[2,4-bis(trichloromethyl)-s-triazine-6-yl]phenylthio}acetate, 2-epoxyethyl-2-{4-[2,4-bis(trichloromethyl)-s-triazine-6-yl]phenylthio}acetate, cyclohexyl-2-{4-[2,4-bis(trichloromethyl)-s-triazine-6-yl]phenylthio}acetate, benzyl-2-{4-[2,4-bis(trichloromethyl)-s-triazine-6-yl]phenylthio}acetate, 3-{chloro-4-[2,4-bis(trichloromethyl)-s-triazine-6-yl]phenylthio}propionic acid, 3-{4-[2,4-bis(trichloromethyl)-s-triazine-6-yl]phenylthio}propionamide, 2,4-bis(trichloromethyl)-6-p-methoxystyryl-s-triazine, 2,4-bis(trichloromethyl)-6-(1-p-dimethylaminophenyl)-1,3-butadienyl-s-triazine, or 2-trichloromethyl-4-amino-6-p-methoxystyryl-s-triazine.

According to embodiments of the disclosure, the composition may further include a solvent, and the ingredients of the composition may be dispersed in the solvent.

According to embodiments of the disclosure, the solid content of the composition may be 1% to 30% (such as about 2%, 5%, 10%, 15%, 20%, or 25%). Herein, the solid content refers to the weight percentage of all ingredients in the composition except for the solvent, based on the total weight of the composition. According to embodiments of the disclosure, the thickness of the polyimide film prepared from the composition is directly proportional to the solid content of the composition. Namely, the thickness of the polyimide film prepared from the composition can be adjusted according to the solid content of the composition.

According to embodiments of the disclosure, the solvent may be benzene, toluene, xylene, ethylbenzene, diethylbenzene, trimethylbenzene, triethylbenzene, cyclohexane, cyclohexene, decahydronaphthalene, dipentene, pentane, hexane, heptane, octane, nonane, decane, ethyl cyclohexane, methyl cyclohexane, p-menthane, dipropyl ether, dibutyl ether, anisole, butyl acetate, pentyl acetate, methyl isobutyl ketone (MIBK), cyclohexylbenzene, cyclohexanone, cyclopentanone (CPN), triglyme (triethylene glycol dimethyl ether), 1,3-dimethyl-2-imidazolidinone (DMI), N-methyl-2-pyrrolidone (NMP), methyl ethyl ketone (MEK), N,N-dimethylacetamide (DMAc), γ-butyrolactone (GBL), N,N-dimethylformamide (DMF), propylene glycol methyl ether acetate (PGMEA), dimethyl sulfoxide (DMSO), cresol, or a combination thereof.

According to embodiments of the disclosure, the polyimide of the disclosure may be prepared by the following steps. First, the diamine, dianhydride, and capping agent (such as amine capping agent, or anhydride capping agent) are added into a reaction bottle and dissolved in a solvent, obtaining a solution. The solid content of the solution may be about 10% to 50% (such as about 11%, 12%, 14%, 15%, 18%, 20%, 21%, 22%, 25%, 27%, 29%, 30%, 32%, 34%, 35%, 38%, 40%, 42%, 44%, 46%, or 48%). The diamine, dianhydride, and capping agent are the same as defined above. According to embodiments of the disclosure, the molar ratio of diamine to dianhydride may be about 1:1.05 to 1.05:1. When the molar amount of diamine used is greater than that of dianhydride, an anhydride capping agent can be added to control the main-chain length of the polyimide. Conversely, when the molar amount of dianhydride used is greater than that of diamine, an amine capping agent can be added to control the main-chain length of the polyimide. According to embodiments of the disclosure, the main-chain length of the polyimide of the disclosure is controlled by the amount of capping agent added. Specifically, the main-chain length of the polyimide is inversely proportional to the amount of capping agent added. In order to increase the number of repeating units in the polyimide main chain, the amount of capping agent can be reduced (i.e., lowering the molar ratio of capping agent to diamine or capping agent to dianhydride). Conversely, in order to decrease the number of repeating units in the polyimide main chain, the amount of capping agent can be increased (i.e., increasing the molar ratio of capping agent to diamine or capping agent to dianhydride).

According to embodiments of the disclosure, in order to enhance the polymerization of polyimide, a catalyst may be optionally added into the solution. Next, after reacting the solution at 180° C.-250° C. for 4 hours-12 hours, a solution containing the polyimide of the disclosure (polyimide solution) is obtained. According to embodiments of the disclosure, the catalyst may be any catalyst suitable for imidization reactions, such as tertiary amines. For example, tertiary amine can include triethylenediamine (DABCO), N,N-dimethylcyclohexylamine, 1,2-dimethylimidazole, trimethylamine, triethylamine, tripropylamine, tributylamine, triethanolamine, N,N-dimethylethanolamine, N,N-diethylethanolamine, triethylenediamine, N-methylpyrrolidine, N-ethylpyrrolidine, N-methylpiperidine, N-ethylpiperidine, imidazole, pyridine, methylpyridine, dimethylpyridine, quinoline, or isoquinoline.

According to embodiments of the disclosure, the composition of the disclosure may consist of the polyimide and the crosslinking agent. According to embodiments of the disclosure, the composition of the disclosure may consist of the polyimide, the crosslinking agent, and the initiator. According to embodiments of the disclosure, the composition of the disclosure may consist of the polyimide, the crosslinking agent, the initiator, and the solvent.

According to embodiments of the disclosure, the composition of the disclosure may substantially consist of the polyimide of the disclosure, the crosslinking agent, the initiator, and the solvent. Namely, the polyimide, the crosslinking agent, and the initiator are the main ingredients of the composition, and the total amount of the polyimide and the crosslinking agent is about 90 wt % to 99.99 wt % (such as 93 wt %, 95 wt %, 98 wt %, 99 wt %, or 99.5 wt %), based on the total weight of the composition.

In addition, except for the polyimide, the crosslinking agent, the initiator, and the solvent, the other ingredients of the composition are defined as the minor ingredient. According to embodiments of the disclosure, the minor ingredient may be a catalyst used to prepare the polyimide, unreacted diamine or dianhydride from the polyimide preparation, an additive, or a combination thereof. The total weight of the minor ingredient accounts for about 0.01 wt % to 10 wt % of the composition. According to embodiments of the disclosure, the additive may be an additive known to those skilled in the art, such as a filler, flame retardant, viscosity modifier, thixotropic agent, defoamer, leveling agent, surface treatment agent, stabilizer, antioxidant, or a combination thereof. According to other embodiments of the disclosure, the composition of the disclosure may consist of the main ingredient and minor ingredient.

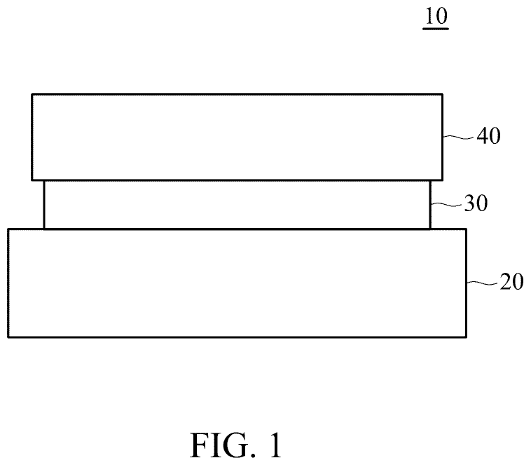

According to embodiments of the disclosure, the disclosure also provides a package structure 10, as shown in FIG. 1. The package structure 10 may include a substrate 20, a polyimide film 30 disposed on the substrate 20, and an electronic element 40 disposed on the polyimide film 30, wherein the polyimide film 30 is a cured product of the composition of the disclosure via a baking process.

According to embodiments of the disclosure, the polyimide film 30 is used to bond the electronic element 40 on the substrate 20, obtaining the package structure 100. According to embodiments of the disclosure, before bonding the electronic element 40 on the substrate 20 with the polyimide film 30, a redistribution layer (RDL) (not shown) may be formed on top of the polyimide film 30, and then the electronic element 40 may be connected to the redistribution layer (RDL).

According to embodiments of the disclosure, the thickness of the polyimide film 30 of the disclosure is not limited and can be optionally modified by a person of ordinary skill in the field. According to embodiments of the disclosure, the average thickness of the polyimide film 30 may be about 1 μm to 500 μm, such as 2 μm, 3 μm, 4 μm, 5 μm, 8 μm, 10 μm, 20 μm, 30 μm, 40 μm, 50 μm, 100 μm, 150 μm, 200 μm, 300 μm, or 400 μm. According to embodiments of the disclosure, the substrate 20 may be a transparent substrate, such as a glass substrate or a polymer film. According to embodiments of the disclosure, the polymer film may be polyethylene terephthalate (PET) film, polybutylene terephthalate (PBT) film, polyethylene (PE) film, polyethylene naphthalate (PEN) film, polypropylene (PP) film, polyvinyl chloride (PVC) film, or polyacrylate film. According to embodiments of the disclosure, the electronic element 40 is not limited and can be optionally modified by a person of ordinary skill in the field. The electronic element 40 may be an optoelectronic device, such as a semiconductor chip, display element, or light-emitting diode (such as an organic light-emitting diode or micro light-emitting diode). The polyimide film prepared from the composition includes polyimide molecular chains and crosslinked segments that can absorb laser light energy in the 200 nm to 300 nm wavelength range. Therefore, it can be irradiated with a laser beam to decompose the polyimide film, thereby disassembling the package structure.

According to embodiments of the disclosure, the package structure 10 may be prepared by the following steps. First, a substrate 20 is provided. Next, the composition of the disclosure is applied on the substrate 20 via a coating process to form a coating. According to embodiments of the disclosure, the coating process may include screen printing, spin coating, bar coating, blade coating, roller coating, dip coating, spray coating, or brush coating. Next, the coating is subjected to a baking process to form the polyimide film 30. The temperature of the baking process may be about 50° C. to 350° C., and the duration of the baking process may be from 30 μminutes to 8 hours. According to embodiments of the disclosure, the baking process may be a one-stage or multi-stage baking process, such as baking at 100° C. to 200° C. for 15 μminutes to 2 hours, and then baking at 200° C. to 350° C. for 15 μminutes to 6 hours. After forming the polyimide film 30, the electronic element 40 can be disposed on top of the polyimide film 30. According to other embodiments of the disclosure, after forming the polyimide film 30, a redistribution layer (RDL) may be formed on the polyimide film 30, and then the electronic element 40 can be disposed on the redistribution layer, allowing the electronic element 40 to connect with the redistribution layer.

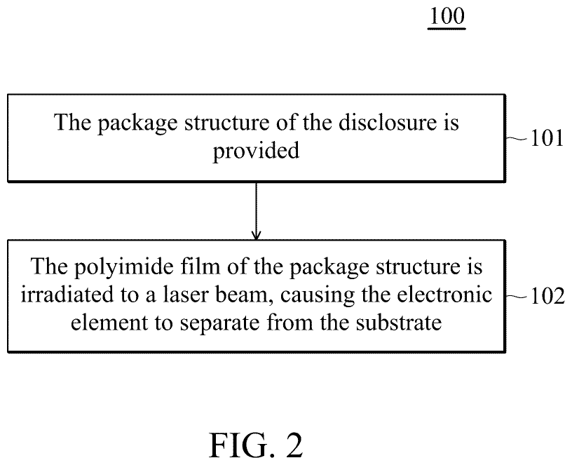

According to embodiments of the disclosure, the disclosure also provides a method 100 for disassembling a package structure. As shown in FIG. 2, the method for disassembling the package structure includes the following steps. First, the package structure of the disclosure is provided (step 101), and then the polyimide film of the package structure is irradiated to a laser beam, causing the electronic element to separate from the substrate (step 102).

According to embodiments of the disclosure, when the polyimide film 30 of the package structure 10 is irradiated with a laser beam (i.e., performing a laser lift-off process on the package structure 10), it can cause the polyimide film 30 to decompose. As a result, the electronic element 40 can be easily peeled off from the substrate 20 without any adhesive residue remaining on the electronic element 40 or causing damage to the electronic element 40, thereby improving the reuse rate of the electronic element and increasing the efficiency of the rework process. According to embodiments of the disclosure, the wavelength of the laser beam may be between 200 nm and 300 nm, and the irradiation intensity of the laser beam may be between 2 μmJ/cm² and 15 μmJ/cm². If the irradiation intensity is too low, it will not effectively disassemble the package structure. When the irradiation intensity is too high, it may cause damage to the electronic element (such as embrittlement, burning, increased resistance, or broken contacts), rendering the electronic element unusable.

Below, exemplary embodiments will be described in detail with reference to the accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

### Preparation of Polyimide

Table 1 lists the reagents involved in the Preparation Examples of the disclosure.

TABLE 1

| abbreviation | name | structure |
|---|---|---|
| 4,4′-ODA | 4,4′-oxydianiline | 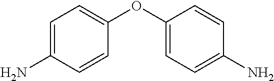 [SMILES: Nc1ccc(Oc2ccc(N)cc2)cc1] |
| TFMB | 2,2′-bis(trifluoromethyl)benzidine | 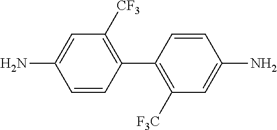 [SMILES: Nc1ccc(-c2ccc(N)cc2C(F)(F)F)c(C(F)(F)F)c1] |
| BAPS | bis[4-(4-aminophenoxy)phenyl] sulfone | 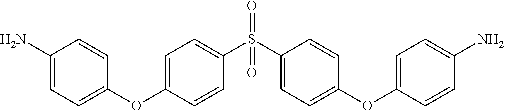 [SMILES: Nc1ccc(Oc2ccc(S(=O)(=O)c3ccc(Oc4ccc(N)cc4)cc3)cc2)cc1] |
| B1317 | bicyclo[2.2.2]oct-7-ene-2,3,5,6- tetracarboxylic dianhydride | 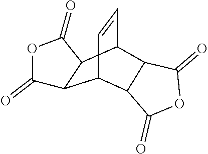 [SMILES: O=C1OC(=O)C2C3C=CC(C12)C1C(=O)OC(=O)C31] |
| H-PMDA | 1,2,4,5-cyclohexanetetracarboxylic dianhydride | 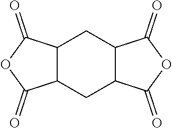 [SMILES: O=C1OC(=O)C2CC3C(=O)OC(=O)C3CC12] |
| 4,4′-BPDA | 3,3′, 4,4′-biphenyl tetracarboxylic dianhydride | 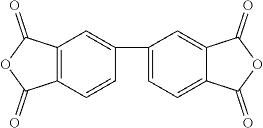 [SMILES: O=C1OC(=O)c2cc(-c3ccc4c(c3)C(=O)OC4=O)ccc21] |
| 6FDA | 4,4′-(hexafluoroisopropylidene)diphthalic anhydride | 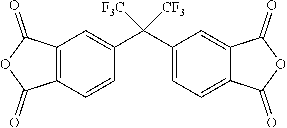 [SMILES: O=C1OC(=O)c2cc(C(c3ccc4c(c3)C(=O)OC4=O)(C(F)(F)F)C(F)(F)F)ccc21] |
| | allylsuccinic anhydride | 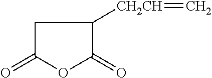 |
| TMPTMA | trimethylolpropane triacrylate | 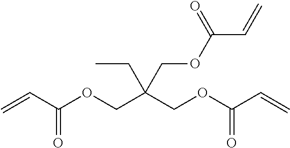 [SMILES: C=CC(=O)OCC(CC)(COC(=O)C=C)COC(=O)C=C] |
| DPHA | dipentaerythritol hexaacrylate | 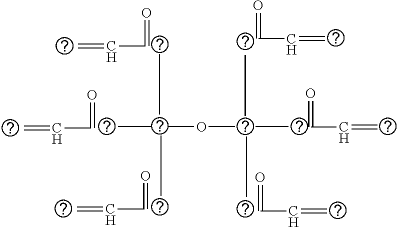 |

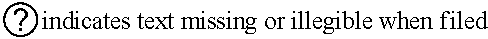

### Preparation Example 1

4,4′-oxydianiline (4,4′-ODA) (serving as diamine), bicyclo[2.2.2]oct-7-ene-2,3,5,6-tetracarboxylic dianhydride (B1317) (serving as dianhydride), 4,4′-(hexafluoroisopropylidene)diphthalic anhydride (6FDA) (serving as dianhydride), and allylsuccinic anhydride (serving as capping agent) were added into a reaction bottle, wherein the molar ratio of diamine and dianhydride was about 1.0044, the molar ratio of B1317 and 6FDA was 1, and the molar ratio of the capping agent and dianhydride was about 0.0177. Next, gamma-butyrolactone (GBL) was added into the reaction bottle, obtaining a solution (with a solid content of about 30%). Next, under a nitrogen atmosphere, the solution was reacted at 220° C. for 6 hours. The result was purified, obtaining Polyimide (1). The evaluation of the number of main-chain repeating units (n value) for Polyimide (1) was conducted, and the results are shown in Table 2. The method for evaluating the number of repeating units (n value) is as follows: the number average molecular weight (Mn) of the polyimide was measured using gel permeation chromatography (GPC) (based on a polystyrene calibration curve). The number of repeating units (n value) was calculated by dividing the obtained number average molecular weight (Mn) by the molecular weight of the main-chain repeating unit.

### Preparation Example 2

Preparation Example 2 was performed in the same manner as in Preparation Example 1, except that the molar ratio of capping agent and dianhydride was reduced to 0.0154, in order to increase the number of main-chain repeating units (n value) of Polyimide (2), and the results are shown in Table 2.

### Preparation Example 3

Preparation Example 3 was performed in the same manner as in Preparation Example 1, except that the molar ratio of capping agent and dianhydride was increased to 0.0221, in order to reduce the number of main-chain repeating units (n value) of Polyimide (3), and the results are shown in Table 2.

### Preparation Example 4

Preparation Example 4 was performed in the same manner as in Preparation Example 1, except that no capping agent was added, obtaining Polyimide (4).

### Preparation Example 5

Preparation Example 5 was performed in the same manner as in Preparation Example 1, except that the molar ratio of capping agent and dianhydride was reduced to 0.011, in order to increase the number of main-chain repeating units (n value) of Polyimide (5), and the results are shown in Table 2.

### Preparation Example 6

Preparation Example 6 was performed in the same manner as in Preparation Example 1, except that 4,4′-ODA was replaced with 2,2′-bis(trifluoromethyl)benzidine (TFMB) (serving as diamine), obtaining Polyimide (6), and the number of main-chain repeating units (n value) of Polyimide (6) is shown in Table 2.

### Preparation Example 7

Preparation Example 7 was performed in the same manner as in Preparation Example 1, except that B1317 and 6FDA were replaced with 3,3′, 4,4′-biphenyl tetracarboxylic dianhydride (BPDA) (serving as dianhydride), obtaining Polyimide (7), and the number of main-chain repeating units (n value) of Polyimide (7) is shown in Table 2.

### Preparation Example 8

Preparation Example 8 was performed in the same manner as in Preparation Example 1, except that 4,4′-ODA was replaced with bis[4-(4-aminophenoxy)phenyl]sulfone (BAPS) (serving as diamine), and B1317 and 6FDA were replaced with 1,2,4,5-cyclohexanetetracarboxylic dianhydride (H-PMDA) (serving as dianhydride), obtaining Polyimide (8), and the number of main-chain repeating units (n value) of Polyimide (8) is shown in Table 2.

TABLE 2

| | diamine | dianhydride | n | n/2 |
|---|---|---|---|---|
| Preparation | 4,4′-ODA | 6FDA/B1317 | ~600 | ~300 |
| Example 1 | | | | |
| Preparation | 4,4′-ODA | 6FDA/B1317 | ~1000 | ~500 |
| Example 2 | | | | |
| Preparation | 4,4′-ODA | 6FDA/B1317 | ~100 | ~50 |
| Example 3 | | | | |
| Preparation | 4,4′-ODA | 6FDA/B1317 | — | — |
| Example 4 | | | (without | (without |
| | | | capping | capping |
| | | | agent) | agent) |
| Preparation | 4,4′-ODA | 6FDA/B1317 | ~1600 | ~800 |
| Example 5 | | | | |
| Preparation | TFMB | 6FDA/B1317 | ~600 | ~300 |
| Example 6 | | | | |
| Preparation | 4,4′-ODA | BPDA | ~600 | ~300 |
| Example 7 | | | | |
| Preparation | BAPS | H-PMDA | ~600 | ~300 |
| Example 8 | | | | |

### Preparation of Composition

### Examples 1-7

Examples 1-7 were prepared by adding polyimide, crosslinking agent, and initiator into a reaction bottle according to the ingredients and contents shown in Table 3. Next, gamma-butyrolactone (GBL) was added into the reaction bottle to dissolve the ingredients, obtaining Compositions (1)-(7) (with a solid content about 30%).

TABLE 3

| | polyimide | crosslinking agent | initiator |
|---|---|---|---|
| Composition (1) | Polyimide (1) | TMPTMA | BPO |
| | 100 parts by | 3.26 parts by weight | 0.78 parts |
| | weight | | by weight |
| Composition (2) | Polyimide (2) | TMPTMA | BPO |
| | 100 parts by | 2.85 parts by weight | 0.68 parts |
| | weight | | by weight |
| Composition (3) | Polyimide (3) | TMPTMA | BPO |
| | 100 parts by | 4.07 parts by weight | 0.97 parts |
| | weight | | by weight |
| Composition (4) | Polyimide (6) | TMPTMA | BPO |
| | 100 parts by | 2.67 parts by weight | 0.64 parts |
| | weight | | by weight |
| Composition (5) | Polyimide (7) | TMPTMA | BPO |
| | 100 parts by | 3.60 parts by weight | 0.86 parts |
| | weight | | by weight |
| Composition (6) | polyimide (8) | TMPTMA | BPO |
| | 100 parts by | 2.72 parts by weight | 0.65 parts |
| | weight | | by weight |
| Composition (7) | Polyimide (1) | DPHA | BPO |
| | 100 parts by | 5.57 parts by weight | 0.78 parts |
| | weight | | by weight |

### Comparative Examples 1-4

Comparative Examples 1-4 were prepared by adding polyimide, crosslinking agent, and initiator into a reaction bottle according to the ingredients and contents shown in Table 4. Next, gamma-butyrolactone (GBL) was added into the reaction bottle to dissolve the ingredients, obtaining Compositions (8)-(11) (with a solid content about 30%).

TABLE 4

| | | crosslinking | |
|---|---|---|---|
| | polyimide | agent | initiator |
| Composition (8) | Polyimide (4) | — | — |
| | 100 parts by weight | | |
| Composition (9) | Polyimide (5) | TMPTMA | BPO |
| | 100 parts by weight | 2.04 parts by | 0.48 parts |
| | | weight | by weight |
| Composition (10) | Polyimide (1) | — | BPO |
| | 100 parts by weight | | 0.78 parts |
| | | | by weight |
| Composition (11) | Polyimide (4) | TMPTMA | BPO |
| | 100 parts by weight | 3.27 parts by | 0.78 parts |
| | | weight | by weight |

### Preparation of Package Structure

### Example 8

A micro-diode (manufactured by Epistar Corporation) was provided. Next, Composition (1) was spin-coated onto a glass substrate at a speed of 1,000 rpm for 60 seconds. After baking at 300° C. for 60 μminutes, a polyimide film (with a thickness of 11 μm) on the glass substrate was obtained. Next, a redistribution layer was formed on the polyimide film, and the micro-diode was placed on the redistribution layer and connected to it, obtaining Package structure (1).

### Examples 9-14 and Comparative Examples 5-8

Examples 9-14 and Comparative Examples 5-8 were performed in the same manner as in Example 8, except that Composition (1) was replaced with Compositions (2)-(11) individually, obtaining Package structures (2)-(11).

### Evaluation of Package Structure

Next, the evaluation of whether the micro-diode in Package structures (1)-(11) can be separated from the glass substrate after a laser lift-off process was conducted. The evaluation method is as follows: a laser machine (commercially available from Kingyoup Optronics Co., Ltd.) was used to irradiate the polyimide film of the package structure with a laser beam at a wavelength of 308 nm (power 2-10 kW, scanning speed 1-5 M/m), and the laser irradiation intensity is shown in Table 5. After the irradiation was completed, the package structure was removed and the micro-diode in package structures (1)-(11) was evaluated for removal from the glass substrate using the cross hatch test (based on ASTM D3359). If the cross hatch test result is GB, it is determined to be removable. Next, after the irradiation process, the glass substrate was observed for any yellowing or scorching, and the results are shown in Table 5.

TABLE 5

| | | | | | | whether |
|---|---|---|---|---|---|---|
| | | | | | | yellowing |
| | | | | | | or |
| | | | | | | scorching |
| | | | | laser | | was |
| | | laser | scanning | irradiation | whether the | observed on |
| | | power | speed | intensity | LED Can Be | the |
| | | (KW) | (M/min) | (mJ/cm2) | removed | substrate |
| Example 8 | Package | 2 | 4 | 2.5 | removable | No |
| | structure | | | | | |
| | (1) | | | | | |
| Example 9 | Package | 2 | 3 | 3.44 | removable | No |
| | structure | | | | | |
| | (2) | | | | | |
| Example 1 0 | Package | 2 | 5 | 2 | removable | No |
| | structure | | | | | |
| | (3) | | | | | |
| Example 11 | Package | 2 | 4 | 2.5 | removable | No |
| | structure | | | | | |
| | (4) | | | | | |
| Example 12 | Package | 2 | 4 | 2.5 | removable | No |
| | structure | | | | | |
| | (5) | | | | | |
| Example 13 | Package | 2 | 4 | 2.5 | removable | No |
| | structure | | | | | |
| | (6) | | | | | |
| Example 14 | Package | 2 | 4 | 2.5 | removable | No |
| | structure | | | | | |
| | (7) | | | | | |
| Comparative | Package | 10 | 1 | 50 | irremovable | — |
| Example 5 | structure | | | | | |
| | (8) | | | | | |
| Comparative | Package | 3 | 1 | 15 | irremovable | — |
| Example 6 | structure | | | | | |
| | (9) | | | | | |
| | Package | 5 | 1 | 25 | removable | scorching |
| | structure | | | | | |
| | (9) | | | | | |
| Comparative | Package | 2 | 4 | 2.5 | irremovable | — |
| Example 7 | structure | | | | | |
| | (10) | | | | | |
| Comparative | Package | 2 | 4 | 2.5 | irremovable | — |
| Example 8 | structure | | | | | |
| | (11) | | | | | |

As shown in Tables 2-5, since the number ratio of the main-chain repeating units and end-capping groups (n/2) of polyimide used in Compositions (1)-(7) is within a range of 10 to 550 and Compositions (1)-(7) included the crosslinking agent, the films prepared from Compositions (1)-(7) are suitable for the laser lift-off process (decomposing with a laser beam irradiation intensity of less than 5 μmJ/cm²), enabling the micro-diode to separate from the package structure. In contrast, the polyimide used in Composition (8) does not employ the capping agent to control the main-chain length during preparation, and even with the further use of crosslinking agents (i.e., Composition (11)), it remains unsuitable for the laser lift-off process. The polyimide used in Composition (9) has an excessively long main-chain length, and despite using the capping agent during the polyimide preparation, it is still not suitable for the laser lift-off process (as it requires higher irradiation intensity, which can easily damage the electronic element). Composition (10) uses polyimide with the specified main-chain length as described in the disclosure, but since it does not include a crosslinking agent, it is also not suitable for the laser lift-off process.

Accordingly, due to the specific polyimide (with the number of main-chain repeating units within a specific range) in combination with a crosslinking agent, the composition of the disclosure becomes suitable for the laser lift-off process and can be applied to package structures. As a result, during the process of transferring the electronic element, the electronic element can be smoothly separated from the substrate without causing damage to the electronic element.

It will be clear that various modifications and variations can be made to the disclosed methods and materials. It is intended that the specification and examples be considered as exemplary only, with the true scope of the disclosure being indicated by the following claims and their equivalents.

What is claimed is:

1. A composition, comprising:
100 parts by weight of a polyimide, wherein the polyimide consists of n number of a main-chain repeating unit and two end-capping groups, wherein n/2 is 10 to 550, wherein the main-chain repeating unit is derived from a reaction of a diamine and a dianhydride; and
1-10 parts by weight of a crosslinking agent.

2. The composition as claimed in claim 1, wherein the end-capping group is derived from a reaction of the diamine and an anhydride compound, or the end-capping group is derived from a reaction of the dianhydride and an amine compound.

3. The composition as claimed in claim 2, wherein the anhydride compound is 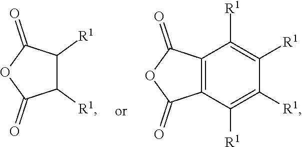
wherein R¹ is independently hydrogen, fluorine, hydroxyl group, amino group, C1-C8 alkyl group, C1-C8 fluoroalkyl group, C6-C12 aryl group, C2-C8 carboxyalkyl group, C2-C8 alkenyl group, C2-C8 isocyanatoalkyl group, C1-C8 alkylamino group, C4-C8 acryloxyalkyl group, C5-C9 methacryloxyalkyl group, C3-C8 epoxyalkyl group, C4-C8 oxetanylalkyl group, or 3,4-epoxycyclohexyl group.

4. The composition as claimed in claim 2, wherein the amine compound is 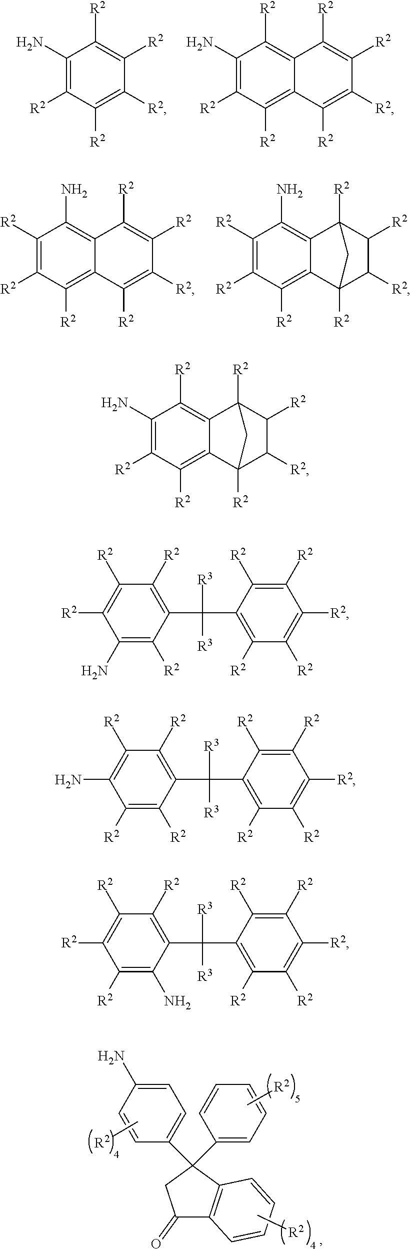 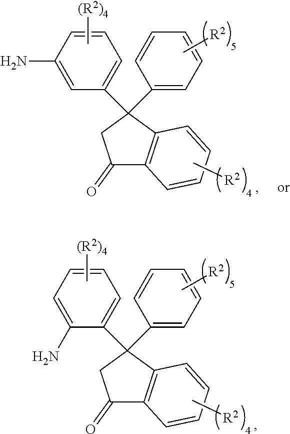
wherein R² is independently hydrogen, fluorine, hydroxyl group, C1-C8 alkyl group, C1-C8 fluoroalkyl group, C6-C12 aryl group, C2-C8 carboxyalkyl group, C2-C8 alkenyl group, C2-C8 isocyanatoalkyl group, C4-C8 acryloxyalkyl group, C5-C9 μmethacryloxyalkyl group, C3-C8 epoxyalkyl group, C4-C8 oxetanylalkyl group, or 3,4-epoxycyclohexyl group; and, R³ is independently hydrogen, fluorine, C1-C4 alkyl group, or C1-C4 fluoroalkyl group.

5. The composition as claimed in claim 1, wherein the diamine is 1,3-bis(4-aminophenoxy)benzene, 3,3′-oxydianiline, 4,4′-oxydianiline, bis(4-aminophenyl) terephthalate, 1,3-bis(3-aminophenoxy)benzene, 4,4′-oxybis[3-(trifluoromethyl)aniline], 2,2-bis[4-(4-aminophenoxy)phenyl]propane, 4,4′-bis(4-aminophenoxy)benzophenone, 4,4′-[naphthalene-2,7-diylbis(oxy)]dianiline, 4,4′-(1,1′-biphenyl-4,4′-diyldioxy)dianiline, 2,2-bis[4-(4-aminophenoxy)phenyl]hexafluoropropane, isophorone diamine, 4-methylcyclohexane-1,3-diamine, 4,4′-methylenebis(cyclohexylamine), 4,4′-methylenebis(2-methylcyclohexylamine), bis(aminomethyl)norbornane, adamantane-1,3-diamine, octahydro-4,7-methanoindene-1(2),5(6)-dimethanamine, 2,2′-bis(trifluoromethyl)benzidine, 2,2′-dimethyl-4,4′-biphenyldiamine, O-tolidine, 4,4′-methylenedianiline, 3,4′-methylenedianiline, 4,4′-diamino-3,3′-dimethyldiphenylmethane, 4,4′-methylenebis(2-ethylbenzenamine), 4,4′-methylenebis(2,6-diethylaniline), 9,10-bis(4-aminophenyl)anthracene, p-phenylenediamine, m-phenylenediamine, o-phenylenediamine, 2,6-naphthalenediamine, 2,6-anthracenediamine, 4,4′-diamino-p-terphenyl, 2,2-bis(4-aminophenyl) hexafluoropropane, α,α′-bis(4-aminophenyl)-1,4-diisopropylbenzene, 9,9-bis(4-aminophenyl)fluorene, 3,3′,5,5′-tetramethylbenzidine, 4,4′-diamino-2,2′-dimethoxybiphenyl, 4,4′-diaminobenzophenone, bis[4-(4-aminophenoxy)phenyl]sulfone, 4,4′-diaminobenzanilide, or a combination thereof.

6. The composition as claimed in claim 1, wherein the dianhydride is 3,4′-oxydiphthalic anhydride, 2,2-bis[4-(3,4-dicarboxyphenoxy)phenyl]propanedianhydride, p-phenylenebis(trimellitate anhydride), 2,6-dihydroxynaphthalene bis(trimellitate anhydride), pyromellitic dianhydride, cyclobutane-1,2,3,4-tetracarboxylic dianhydride, 1,2,4,5-cyclohexanetetracarboxylic dianhydride, bicyclo[2.2.2]oct-7-ene-2,3,5,6-6 tetracarboxylic dianhydride, bicyclooctanetetracarboxylic dianhydride, dicyclohexyl-27 3,4,3′,4′-tetracarboxylic dianhydride, 3-(carboxymethyl)-1,2,4-cyclopentanetricarboxylic acid 1,4:2,3-dianhydride, 1,2,3,4-butanetetracarboxylic dianhydride, 3,3′, 4,4′-biphenyl tetracarboxylic dianhydride, 2,3,3′,4′-biphenyltetracarboxylic dianhydride, 5-[4-(1,3-dioxo-2-benzofuran-5-yl)phenyl]-2-benzofuran-1,3-dione, 5-[3-(1,3-dioxo-2-benzofuran-5-yl)phenyl]-2-benzofuran-1,3-dione, 4,4′-(hexafluoroisopropylidene)diphthalic anhydride, 3,3′, 4,4′-benzophenonetetracarboxylic dianhydride, 9,9-bis(3,4-dicarboxyphenyl)fluorene dianhydride, N,N′-(2,2′-bis(trifluoromethyl)-[1,1′-biphenyl]-4,4′-diyl)bis(1,3-dioxo-1,3-dihydroisobenzofuran-5-carboxamide), 1,2,3,4-cyclopentanetetracarboxylic dianhydride, or a combination thereof.

7. The composition as claimed in claim 1, wherein the diamine and the dianhydride have a molar ratio of 1:1.05 to 1.05:1.

8. The composition as claimed in claim 1, wherein the crosslinking agent is a compound having at least two reactive groups, wherein the reactive group is isocyanato group, hydroxy group, epoxy group, acryloxy group, or methacryloxy group.

9. The composition as claimed in claim 1, wherein the crosslinking agent is trimethylol propane triglycidyl ether, glycerol triglycidyl ether, glycerol propoxylate triglycidyl ether, N,N-diglycidyl-4-glycidyloxyaniline, tris(2,3-epoxypropyl)isocyanurate, o-cresol novolak epoxy resin, triphenylol methane triglycidyl ether, 4,4′-methylenebis(N,N-diglycidylaniline), tetraphenylolethane glycidyl ether, poly(ethylene adipate) diol, poly(1,4-butylene adipate) diol, poly(ethylene dodecanoate) diol, poly(1,6-hexathylene adipate) diol, polyethylene glycol, polypropylene glycol, polytetramethylene ether glycol, ethylene glycol, 1,3-propylene glycol, glycerol, 1,4-butylene glycol, 1,5-pentylene glycol, neopentylene glycol, 1,6-hexylene glycol, 1,7-heptylene glycol, 2,5-furandiol, toluene diisocyanate, phenylene diisocyanate, 4,4′-diphenyl diisocyanate, naphthalene diisocyanate, diphenylmethane diisocyanate, toluidine diisocyanate, hexamethylene diisocyanate, trimethylhexamethylene diisocyanate, 2,6-diisocyanate methyl caprate, 1,3-cyclopentane diisocyanate, norbornane diisocyanate, bis(isocyanatomethyl)cyclohexane, 1,6-hexanediol diacrylate, 1,6-hexanediol dimethacrylate, 1,9-bis(acryloyloxy)nonane, 1,9-bis(methacryloyloxy)nonane, 1,10-decanediol diacrylate, 1,10-decanediol dimethacrylate, neopentyl glycol diacrylate, neopentyl glycol dimethacrylate, polyethylene glycol (200) diacrylate, polyethylene glycol (400) diacrylate, pentaerythritol tetraacrylate, dipentaerythritol hexaacrylate, di(trimethylolpropane) tetraacrylate, trimethylolpropane triacrylate, di(polypentaerythritol) polyacrylate, polypentaerythritol polyacrylate, polybutadiene diacrylate, 3-methyl 1,5-pentanediol diacrylate, ethoxylated bisphenol A diacrylate, propoxylated trimethylolpropane triacrylate, ethoxylated pentaerythritol tetraacrylate, ethoxylated trimethylolpropane triacrylate, esterdiol diacrylate, alkoxylated diacrylate, propoxylated neopentyl glycol diacrylate, propoxylated glyceryl triacrylate, urethane 6 acrylate resin, or a combination thereof.

10. The composition as claimed in claim 1, further comprising:
0.1-2 parts by weight of an initiator.

11. The composition as claimed in claim 1, further comprising:
a solvent, wherein a solid content of the composition is 2% to 20%.

12. A package structure, comprising:
a substrate;
a polyimide film disposed on the substrate, wherein the polyimide film is a cured product of the composition as claimed in claim 1; and
an electronic element disposed on the polyimide film.

13. The package structure as claimed in claim 12, wherein the electronic element is a semiconductor chip, a display element, or a light-emitting diode.
